(19) United States
(12) Patent Application Publication
(10) Pub. No.: US 2023/0330751 A1
(43) Pub. Date: Oct. 19, 2023

(54) ELECTRON GUN CATHODE TECHNOLOGY

(71) Applicant: Freemelt AB, Mölndal (SE)

(72) Inventors: Ulric LJUNGBLAD, Mölndal (SE); Robin STEPHANSEN, Mölndal (SE)

(73) Assignee: Freemelt AB, Mölndal (SE)

(21) Appl. No.: 17/761,864

(22) PCT Filed: Sep. 23, 2020
(86) PCT No.: PCT/EP2020/076485

§ 371 Date: Mar. 18, 2022

(30) Foreign Application Priority Data
Sep. 23, 2019 (SE) 1951071-8

(51) Int. Cl. B33Y 30/00; H01J 37/075; B22F 12/41; H01J 37/305

(52) U.S. Cl. CPC B22F 12/41; B33Y 30/00; H01J 37/075; H01J 37/305

(57) ABSTRACT

A metal 3D printer, a cathode holder system, a carrier for an electron emitter, and an electron source piece with a thermal break in a mechanical interface are provided. The metal 3D printer has an electron gun adapted to direct an electron beam generated by a back heated electron emitter of a cathode arrangement onto a metal material via an anode arrangement. The back heated electron emitter is capable of emitting electrons via thermionic emission from an emitting surface when heated on a back surface, and includes a side surface, essentially perpendicular to the emitting surface, between the emitting surface and the back surface. The metal 3D printer 100 includes: an electron source piece, including the electron emitter attached to a carrier in such a way that the carrier covers the side surface of the electron emitter adjoining the emitting surface; a cathode holder system including one or more cathode holder system members adapted to hold the electron source piece in a position in relation to an anode arrangement; and a first thermal break in a first mechanical interface adapted to mate an emitter holder of the cathode holder system with the electron source piece.

### TECHNICAL FIELD

The present disclosure is in general directed to metal 3D printers and to components suitable for metal 3D printers and other apparatus using electron guns. More particularly, the present disclosure is directed to a metal 3D printer and cathode technology in an electron gun based on a back heated cathode emitter.

### BACKGROUND

Additive manufacturing by metal 3D printing is gaining increasing importance, particularly in industrial fields where geometrically complicated machine parts, often with high quality demands, are manufactured in small series. With the development of metal 3D printing technology in research and in the manufacturing sector, it is currently at a stage where precision, repeatability and the range of available materials allows metal 3D printing to be an industrial production technology for wider applicability.

The quality of metal 3D printed artifacts is heavily dependent on the quality of the beam of electrons delivered by the electron gun. The quality of an electron beam is in its turn dependent on how an electron source is mounted, thermally insulated, and positioned in an electron gun in a metal 3D printer. An electron source is in this context also known as an electron emitter or in short emitter. The maintenance of a high quality electron beam in a metal 3D printer is a major cost driver in terms of manufacturing, assembling, replacing and adjusting consumable parts of an electron gun.

Other applications of electron guns share or have similar needs for a high quality electron beam.

### RELATED ART

EP 1587 129 B1 describes a charged particle emitter arrangement, and proposes to reduce heat losses by minimising the area of contact between the emitter and the emitter carrier.

JP 2009-158365 describes an ion source comprising an emitter carrier in the form of a lock wire. By using such a lock wire, heat transfer loss from the emitter to the cathode holder is minimized, due to the wire shape minimizing of the area of contact between the emitter and the lock wire as well as the area of contact between the lock wire and the cathode holder.

### PROBLEMS WITH THE PRIOR ART

In both EP 1 587 129 B1 and JP 2009-158365, the area of contact between the emitter and the emitter carrier is minimised. This means that the side surface of the emitter is uncovered, and that electrons thus can “leak” also from this side surface, making it more difficult to focus the beam into a tight “spot”. This lowers the quality of the electron beam.

### OBJECT OF EMBODIMENTS

A general object of embodiments described in the present disclosure is to provide a cost efficient cathode technology for electron guns capable of generating a high quality electron beam for metal 3D printers and other applications.

### SUMMARY

Embodiments described in this disclosure comprise a metal 3D printer having an electron gun adapted to direct an electron beam of a cathode arrangement onto a metal material via an anode arrangement. The electron beam is preferably generated by a back heated electron emitter, capable of emitting electrons via thermionic emission from an emitting surface when heated on a back surface, and comprising a side surface, essentially perpendicular to the emitting surface, between the emitting surface and the back surface. The metal 3D printer preferably comprises: an electron source piece, comprising the electron emitter attached to a carrier in such a way that the carrier covers the side surface of the electron emitter adjoining the emitting surface; a cathode holder system comprising one or more cathode holder system members adapted to hold the electron source piece in a position in relation to an anode arrangement; and a first thermal break in a first mechanical interface adapted to mate an emitter holder of the cathode holder system with the electron source piece. The back surface of the electron emitter may in embodiments be covered with a material preventing electron emission.

The emitter carrier is preferably shaped so that no electrons can leak from the side surface of the electron emitter. The electron emitter is preferably arranged in the emitter carrier in such a way that the emitting surface does not extend substantially beyond the emitter carrier. If the emitting surface is curved or domed to be more lens-shaped, there may be parts in the center of the emitting surface that extend beyond the carrier, but the side surface of the electron emitter should preferably always be covered by the carrier.

The cathode holder system may comprise a set of one or more cathode holder system members geometrically form fitting in a series into a cathode assembly such that the cathode holder system members each attains a predefined position in relation to the other cathode holder system members when assembled.

An electron emitter is a consumable article and needs be exchanged for a fresh electron emitter from time to time. The cathode holder system of embodiments herein enables the electron source piece to easily come in a well-defined position. Embodiments of the cathode holder system of the metal 3D printer comprise one or more thermal breaks in one or more mechanical interfaces between the different parts of the cathode holder system, or between the cathode holder system and the electron source piece. The purpose and the effect of the one or more thermal breaks is to reduce the transfer of thermal energy from the emitter to the surrounding cathode holder system. The one or more mechanical interfaces are adapted to provide form fitting as well as galvanic contact, also called electrical contact, between the parts of the cathode holder system.

Embodiments disclosed herein enable cost efficient manufacturing, mounting, replacing and maintenance of an electron gun, as well as allowing for a high quality electron beam.

### BRIEF DESCRIPTION OF DRAWING

Embodiments disclosed herein will be further explained below with reference to the enclosed drawings, in which:

FIG. 1 schematically shows a metal 3D printer with a cathode holder system in accordance with embodiments of the present disclosure.

FIG. 2 schematically shows the cathode holder system of FIG. 1 in an exploded view.

FIGS. 3A-3F schematically show embodiments of electron source pieces, emitter carriers and parts thereof in accordance with embodiments of the present disclosure.

FIG. 4 schematically shows an embodiment of an electron source piece in accordance with embodiments of the present disclosure.

FIGS. 5A-B schematically shows an embodiment of a cathode holder in accordance with embodiments of the present disclosure.

FIG. 6 schematically shows an embodiment of a carrier arrangement in accordance with embodiments of the present disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION OF EMBODIMENTS

Embodiments described in this disclosure comprise a metal 3D printer having an electron gun adapted to direct an electron beam of a cathode arrangement onto a metal material via an anode arrangement. The electron beam is preferably generated by a back heated electron emitter, capable of emitting electrons via thermionic emission from an emitting surface when heated on a back surface, and comprising a side surface, essentially perpendicular to the emitting surface between the emitting surface and the back surface. The metal 3D printer preferably comprises: an electron source piece, comprising the electron emitter attached to a carrier in such a way that the carrier covers the side surface of the electron emitter adjoining the emitting surface; a cathode holder system comprising one or more cathode holder system members adapted to hold the electron source piece in a position in relation to an anode arrangement; and a first thermal break in a first mechanical interface adapted to mate an emitter holder of the cathode holder system with the electron source piece. The electron emitter is preferably arranged in the emitter carrier in such a way that the emitting surface does not extend substantially beyond the emitter carrier, at least the part of the emitter carrier adjoining the emitting surface. If the emitting surface is curved or domed to be more lens-shaped, there may be parts in the center of the emitting surface that extend beyond the carrier, but the side surface of the electron emitter should preferably always be covered by the carrier. The back surface of the emitter is not necessarily parallel with the emitting surface. The back surface of the emitter may in embodiments be covered with a material preventing electron emission. The cathode holder system and embodiments of the disclosure are for example applicable in additive manufacturing apparatus, electron beam welding machines and electron microscopes.

An electron emitter is a consumable article and needs be exchanged for a fresh electron emitter from time to time. The cathode holder system of embodiments herein enables an electron source piece attached to the cathode holder system to come in a well-defined position. Embodiments of the cathode holder system of the metal 3D printer comprise one or more thermal breaks in one or more mechanical interfaces between the different parts of the cathode holder system, or between the cathode holder system and the electron source piece. The purpose and the effect of the one or more thermal breaks is to reduce the transfer of thermal energy from the emitter to the surrounding cathode holder system. The one or more mechanical interfaces are adapted to provide form fitting as well as galvanic contact, also called electrical contact, between the parts of the cathode holder system.

The energy beam generator for back heating of the electron emitter may in variants of the embodiments shown herein be a laser, such as a CO2 laser, generating an energy beam carrying laser light energy in a laser beam, an IR light source generating an energy beam carrying thermal energy in IR light in IR light beam, and/or an electron gun devised and adapted to generate an energy beam in the form an electron beam carrying kinetic energy.

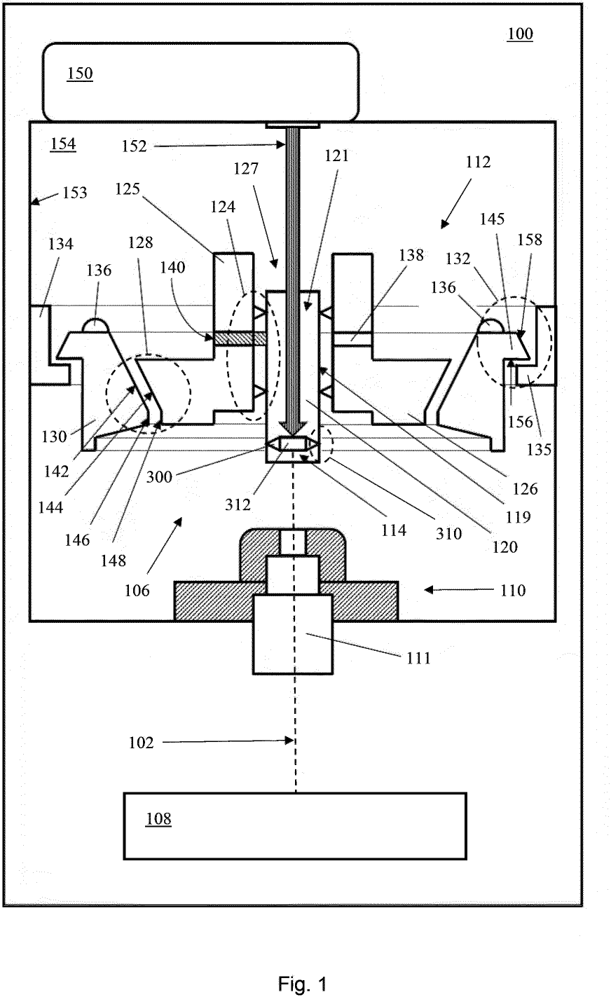

FIG. 1 shows schematically embodiments of a metal 3D printer 100 comprising an energy beam generator 150 adapted to generate an energy beam 152 to heat the back side of an electron emitter 312 mounted via an emitter carrier 300 in a cathode holder system 112 in a vacuum chamber 154. The back side of the electron emitter may in embodiments be covered with a material preventing electron emission. The emitter 312, when radiated with an energy beam 152, emits an electron beam 102 into an electron channel 111 of an anode arrangement 110. Electron beam heating works only in a vacuum environment and therefore it is important that the vacuum chamber 154 maintains high quality vacuum. In embodiments, the metal 3D printer is of a type where an electron beam is radiated onto a metal material. The metal 3D printer then also comprises beam focusing and beam positioning equipment (not shown) between the anode arrangement 110 and the metal material. In the exemplifying embodiment shown in FIG. 1, the metal material is a metal powder deposited on a powder bed 108. This kind of metal 3D printer may use a powder bed system, directed energy deposition (DED), or laser metal deposition (LMD) when a laser is used. In other embodiments, the metal 3D printer is of a type using a deposition technology called electron beam additive manufacturing (EBAM), where an electron beam is used to melt and fuse a metal wire, for example a titanium wire. In embodiments the laser is for example a CO2 laser. In operation, a high voltage in the range of for example 60 kVolt is applied over the cathode and the anode in a per se known manner.

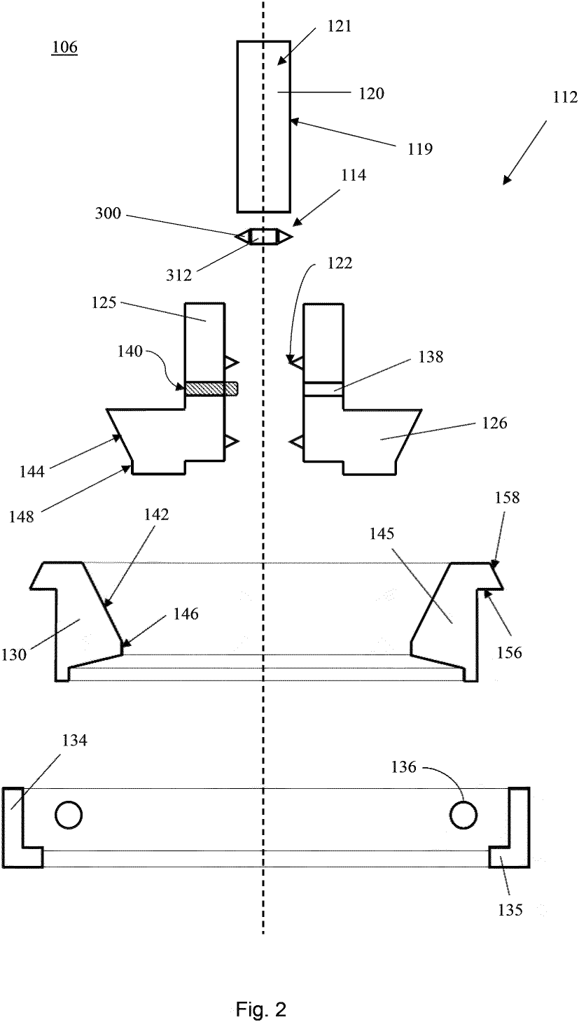

FIG. 1 and FIG. 2 in the exploded view further show embodiments of a cathode holder system 112, that in different embodiments comprises cathode holder system members in a selection of one or more of:
an emitter holder 120 adapted to hold an electron source piece 114, comprising an emitter carrier 300 for an electron emitter 312 and an electron emitter 312 attached to the emitter carrier 300;
an intermediate holder 126 adapted to hold the emitter holder 120;
an outer holder 130 adapted to hold the emitter holder 126, where the outer holder 130 is held by a cathode assembly holder 134 adapted to hold the outer holder 130, and thereby the whole cathode holder system 112.

The material of the respective holders are, in exemplifying embodiments, steel or brass, or a combination of different materials in the different holders.

The electron gun of embodiments herein is preferably of a type called gridless electron gun, which has no more than two electrodes in the form of a cathode and an anode. In this kind of electron gun, the electron stream is controlled by means of the temperature of the emitter, preferably the temperature of the back surface side of the emitter. An advantage with this in the embodiments disclosed herein is that the electron beam looks substantially alike or similar with all electron streams.

### A Metal 3D Printer and Cathode Holder System

Thus, FIG. 1 shows schematically an embodiment of a metal 3D printer 100 adapted to direct an electron beam 102, generated by a back heated electron emitter 312 of a cathode arrangement 106, via an anode arrangement 110, onto a material for melting, such as a powder bed 108. The metal 3D printer 100 as shown in FIG. 1 comprises a cathode holder system 112 with a set of cathode holder system members adapted to hold a cathode in the form of the electron source piece 114 with the emitter 312 in a position in relation to an anode arrangement 110. A first thermal break in a first mechanical interface 310 is adapted to mate an emitter holder 120 of the cathode holder system 112 with the electron source piece 114.

In advantageous variants of embodiments, a metal 3D printer further comprises a laser adapted to generate an energy beam for heating the back of the electron emitter, the laser for example being a CO2 laser. The back of the electron emitter may in embodiments be covered with a material preventing electron emission.

### Emitter Holder & First Thermal Break in First Mechanical Interface

The emitter holder 120 preferably has the shape of a tube, preferably a cylindrical tube, and has its part of the first mechanical interface 310 preferably close to one end of the cylindrical tube. The first mechanical interface 310, schematically indicated within an intermittently drawn oval in FIG. 1, is preferably adapted such that it provides shape locking of the electron source piece 114. The first mechanical interface 310 preferably comprises mating parts in the electron source piece 114 and in the emitter holder 120, respectively.

In embodiments, the emitter holder part of the first mechanical interface 310 is a circular groove at the inside envelope of the cylindrical emitter holder 120. In such embodiments, a pointed or edged shape at one or more contact points of an electron source piece 114 is comprised in the first mechanical interface 310 and is adapted for mating with the groove of said emitter holder 120. Thereby, there is a minimal contact surface between the electron source piece 114 and the emitter holder 120, and a first thermal break is formed such that a minimum of thermal energy can pass by conduction from the electron source piece 114 to the emitter holder 120 while electrical contact is enabled. The first mechanical interface 310 is preferably adapted such that an electron source piece 114 can be snapped in place when attaching it to, and snapped loose when detaching it from, the emitter holder 120.

The shape of the emitter holder 120 may, as described in the above embodiment, be in the form of a cylindrical tube, and may in other embodiments be in the form of a tube a with some other suitable cross-section, such as a square, rectangular, triangular, hexagonal, octagonal, or any other cross section. The emitter holder 120 preferably has an inner channel 121 with a cross section area or diameter that allows the accommodation of an electron source piece 114 with an emitter 312 mounted on an emitter carrier 300 in the channel 121, as well as allowing the free passage of an energy beam 152 directed to a back side of the emitter 312. The back side of the emitter 312 faces the direction from which an energy beam is radiated.

By having the emitter 312 attached inside the tubular emitter holder 120, the emitter 312 is thermally insulated on one hand from thermal conduction by the thermal break of the first mechanical interface 310 between the emitter holder 120 and the emitter carrier 300, and on the other hand by the tubular emitter holder 120 absorbing heat transferred by thermal radiation from the emitter 312. In operation, there is vacuum in the vacuum chamber 154 and there is none or insignificant heat transfer by thermal convection. The wall thickness of the tubular emitter holder 120 is preferably selected such that it allows the provision of the emitter holder part of the first mechanical interface 310, for example a groove as exemplified above, enabling a stable mechanical and electrical connection with the mating part of an electron source piece 114. The length of the tubular emitter holder 120 is preferably selected such that it allows on one hand the absorption of a certain amount of thermal energy, and on the other hand a stable attachment to an intermediate holder 126.

The emitter holder 120 and its emitter holder channel 121 are preferably symmetric around a common center axis parallel with the elongate extension of the emitter holder 120. In embodiments that are preferred for the purpose of simple and accurate manufacturing as well as for simple and accurate fitting, the cross sections of the emitter holder 120 and the emitter holder channel 121 are rotationally symmetrical.

### Intermediate Holder & Second Thermal Break in Second Mechanical Interface

Embodiments of the cathode holder system 112 further comprise, as shown in FIG. 1 and FIG. 2, a second thermal break 122 in a second mechanical interface 124 adapted to mate the emitter holder 120 with an intermediate holder 126 of the cathode holder system 112.

The intermediate holder 126 comprises a body having a tapered peripheral surface 144 in the shape of a truncated cone that tapers smoothly from a first end surface having a larger cross section area than a second end surface having a smaller cross section area. In embodiments, the truncated cone may preferably have a circular cross section, and in other embodiments the truncated cone may be in the form of truncated pyramids having a polygonal cross section. In embodiments, the truncated cone may end with a straight peripheral surface 148 having a cylindrical or polygonal cross section.

The intermediate holder 126 further comprises an intermediate holder channel 127 along a center axis preferably in common with the center axis of the tapered peripheral surface 144 and the straight peripheral surface 148. In embodiments that are preferred for simple and accurate manufacturing as well as for simple and accurate fitting, the cross sections of the emitter holder 120 and the emitter holder channel 121 are rotationally symmetrical. In embodiments, as shown in FIG. 1, the intermediate holder 126 further comprises a collar 125 elongating the intermediate holder channel 127.

An embodiment of the second mechanical interface 124 is schematically indicated within an intermittently drawn oval in FIG. 1. In embodiments, the intermediate holder part of the second mechanical interface 124 comprises one or more edged ridges, continuous or intermittently distributed on the inside envelope surface of the intermediate holder channel 127. In other embodiments, there are one or more pointed tips distributed on the inside envelope of the intermediate holder channel 127. There may also be a combination of edged ridges and pointed tips, or a similar arrangement, on the inside envelope surface of the intermediate holder channel 127.

In such embodiments, an emitter holder 120 is mated with the intermediate holder 126 in the intermediate holder channel 127 by form fitting between the edged or pointed intermediate holder parts and the outer envelope surface 119 of the emitter holder 120. The pointed or edged shape at one or more contact points of the emitter holder 120 comprised in the second mechanical interface are thus adapted for mating with the outer envelope surface of said emitter holder 120. Thereby, there is a minimal contact surface between the emitter holder 120 and the intermediate holder 126, and a second thermal break 122 is formed such that a minimum of thermal energy can pass by conduction from the emitter holder 120 to the intermediate holder 126 while electrical contact is enabled.

The form fitting of the second mechanical interface 124 is preferably adapted to have a tight fit between the mating emitter holder 120 and intermediate holder 126, and with a sliding clearance such that the emitter holder 120 can be attached to and detached from the intermediate holder 126. Preferably, the second mechanical interface 124 is adapted such that a center axis of the emitter holder channel 121 substantially coincides with a center axis of intermediate holder channel 127 when the emitter holder 120 is mated with the intermediate holder 126. The sliding clearance also enables adjustment of the emitter holder 120 along the intermediate holder channel 127 into a selected position. Embodiments, such as the embodiment shown in FIG. 1, may further comprise one or more threaded bores 138, here in the intermediate holder collar 125, for one or more lock screws 140 adapted to enable locking of the emitter holder 120 in a selected position in the intermediate holder channel 127. Such a lock screw would have a pointed tip to engage the emitter holder with a small contact surface also forming a thermal break. Such bore 138 and lock screw 140 may be part of the second mechanical interface 124.

### Outer Holder & Third Mechanical Interface

Embodiments of the cathode holder system 112 further comprise, as shown in FIG. 1 and FIG. 2, a third mechanical interface 128 adapted to mate the intermediate holder 126 with an outer holder 130 of the cathode holder system 112 adapted to form fittingly lock the intermediate holder 126 in a position such that a center axis of the intermediate holder 126 substantially coincides with a center axis of the outer holder 130.

The outer holder 130 comprises a substantially ring shaped body having an annulus 142 comprising an inner surface in the shape of a truncated cone 142 that tapers smoothly from a first end surface having a larger cross section area than a second end surface having a smaller cross section area. The annulus of the outer holder 130 is adapted to mate with the intermediate holder 126, and the annulus of the outer holder 130 is adapted to have a cross section similar to or fitting with the peripheral surface 144 of the intermediate holder 126. As with the intermediate holder, in embodiments the truncated cone may preferably have a circular cross section, and in other embodiments the truncated cone may be in the form of truncated pyramids having a polygonal cross section. In embodiments, the truncated cone of the outer holder 130 may end with a straight annular surface 146 having a cylindrical or polygonal cross section and adapted to mate with a correspondingly shaped straight peripheral surface 148 of the intermediate holder 126.

The annulus 142 has a center axis that is preferably in common with the center axis of a perimeter of the outer holder 130. In embodiments that are preferred for simple and accurate manufacturing as well as for simple and accurate fitting, the cross sections of the annulus 142 and the perimeter or perimeter surfaces of the outer holder are rotationally symmetrical.

An embodiment of the third mechanical interface 128 is schematically indicated within an intermittently drawn circle in FIG. 1. In embodiments, the third mechanical interface 128 comprises the tapered peripheral surface 144 of the intermediate holder 126 and the similarly tapered annular surface 142 of the outer holder 130 that are adapted to mate and form fittingly lock with a surface to surface contact in an end position enabling mechanical stability, position accuracy and electric contact. Embodiments of the third mechanical interface may comprise tapered grooves on the outer holder 130 and correspondingly shaped ridges on the intermediate holder, or vice versa, not shown in the drawings.

In FIG. 1, the intermediate holder 126 and the outer holder 130 are drawn with a clearance between them in the third mechanical interface 128 for illustrative purpose only. When these parts are mounted in the mating position there is as mentioned above surface to surface contact.

The ring shape and the annulus of the outer holder are herein understood to have circular, polygonal or jagged inner or outer contours or cross sections.

The outer holder 130 further comprises one or more perimeter flanges 145 having a substantially flat abutting surface 156, preferably in a plane substantially perpendicular to a center axis of the outer holder 130. In embodiments, the perimeter flange 145 further comprises a tapered perimeter surface 158.

### Cathode Assembly Holder & Fourth Mechanical Interface

Embodiments of the cathode holder system 112 further comprise, as shown in FIG. 1 and FIG. 2, a fourth mechanical interface 132 adapted to mate the outer holder 130 with a cathode assembly holder 134 of the cathode holder system 112, such that the outer holder 130 is steplessly adjustable in a direction at an angle with, preferably perpendicular to, said center axis of said outer holder 130. The cathode assembly holder 134 is adapted to hold an assembly of one or more cathode holder system members 120, 126, 130.

The cathode assembly holder 134 is adapted to be fastened to a chassis 153 of the vacuum chamber 156, as schematically shown in FIG. 1, or to another machine part mounted to the vacuum chamber chassis 153. So for example, the cathode assembly holder may be mounted for example like a balcony on a high voltage feed-through unit arranged at the vacuum chamber to provide a high voltage between the cathode and the anode, not shown in the drawings.

The cathode assembly holder 134 preferably has a recess adapted to receive and accommodate the outer holder 130, and one or more assembly holder flanges 135 adapted to receive the abutting surface 156 of the perimeter flange 145 of the outer holder 130. When the outer holder 130 is placed in the cathode assembly holder 134, the abutting surface 156 of the outer holder 130 rests on the one or more assembly holder flanges 135. In FIG. 1, the mating surfaces are shown with a clearance for illustrating purpose.

For example, the recess of the cathode assembly holder 134 may be annular with an annulus having a cross section similar to the cross section of the perimeter of the outer holder 130. As mentioned above, a circular cross section is preferred, but polygonal or jagged cross sections are conceivable in embodiments.

An embodiment of the fourth mechanical interface 132 is schematically indicated within an intermittently drawn circle in FIG. 1. In embodiments, the fourth mechanical interface 132 comprises the one or more assembly holder flanges 135 of the cathode assembly holder 134 and the abutting surface 156 of the one or more perimeter flanges 145 of the outer holder 130. Further embodiments, as schematically shown in FIG. 1, further comprise a tapered perimeter surface 158 on the perimeter flange 145 of the outer holder 130, and one or more threaded bores 136 on the cathode assembly holder 134. The threaded bores 136 are adapted to accommodate one or more adjustment and locking screws (not shown), such that the tips of the one or more adjustment and locking screws engages the tapered perimeter surface 158. This enables a lateral position of the outer holder 130 within the cathode assembly holder 134 to be set in a stepless fashion while pressing the abutting surface 156 of the outer holder 130 towards the assembly holder flange 135 of the cathode assembly holder 134. Thereby a surface to surface contact enabling mechanical stability, position accuracy and electric contact is attained between the outer holder 130 and the cathode assembly holder 134.

### Electron Source Piece

In an embodiment of the metal 3D printer the cathode holder system 112, as schematically shown in FIG. 1 and FIG. 2, comprises an electron source piece 114 having an emitter 312 attached to a carrier 300, the emitter 312 being capable of emitting electrons via thermionic emission from an emitting surface when heated on a back surface. The back surface of the emitter 312 may in embodiments be covered with a material preventing electron emission. The carrier 300 that is schematically shown in FIG. 1 and FIG. 2 is shaped so that it creates a first thermal break in a first mechanical interface 310 devised for mechanically mating with the emitter holder 120, while at the same time covering the side surface of the emitter 312, so that no electrons can leak from this side surface. The first thermal break and the first mechanical interface 310 have been explained above.

The material of the one or more parts comprised in the carrier 300 or in the carrier part of the electron source piece 114 is preferably selected such that it is stable against electron emission and does not emit electrons, such as electrons, at the temperature ranges that incurs electron emission from a selected emitter 312. Thus, the material of the emitter carrier 300 and emitter carrier parts is preferably selected from a group of materials that lacks or has a minimum of electron emission properties at the temperature or in the temperature ranges where a selected emitter material has electron emitting properties that are suitable for a selected application. Examples of such materials and material combinations are further described below.

The emitter 312 of the electron source piece 114 is a consumable that needs be replaced from time to time after having been consumed. The emitter 312 is replaced by sliding out the emitter holder 120 from the intermediate holder channel 127 after, as in some embodiments, having released lock screws 140, detaching the electron source piece 114 with the consumed emitter 312 from the emitter holder 120, and attaching another electron source piece 114 with a fresh emitter 312 to the emitter holder 120 at the first mechanical interface 310. The emitter holder 120 with the fresh emitter 312 is then slided back into the intermediate holder channel 127 and engaged with the second mechanical interface 124.

Assembled cathode holder system members of cathode holder system in metal 3D printer Embodiments of the cathode holder system 112 of the metal 3D printer, as shown in FIG. 1 and FIG. 2, further comprise a selection of one or more cathode holder system members 120, 126, 130 of the cathode holder system 112, which cathode holder system members are adapted to form fit in a series such that each cathode holder system member attains a predefined position in relation to the other cathode holder system members when assembled.

In further embodiments, the metal 3D printer is such that a selection of one or more cathode holder system members 120, 126, 130 of the cathode holder system 112 are adapted to form fit in a position along an axis substantially in parallel with the direction of an energy beam directed to the back of an electron emitter 312 of an electron source piece 114 and/or substantially in parallel with an electron beam 102 emitted from an emitter 312 towards an anode arrangement 110.

This enables the position of an assembled cathode holder system 112 to be adjusted and fixed with its center axis in a desired position in relation to the direction of the energy beam 152 and/or to the direction of the electron beam 102, as schematically shown in the embodiment shown in FIG. 1.

### Emitter Carrier Piece & Carrier for an Electron Emitter

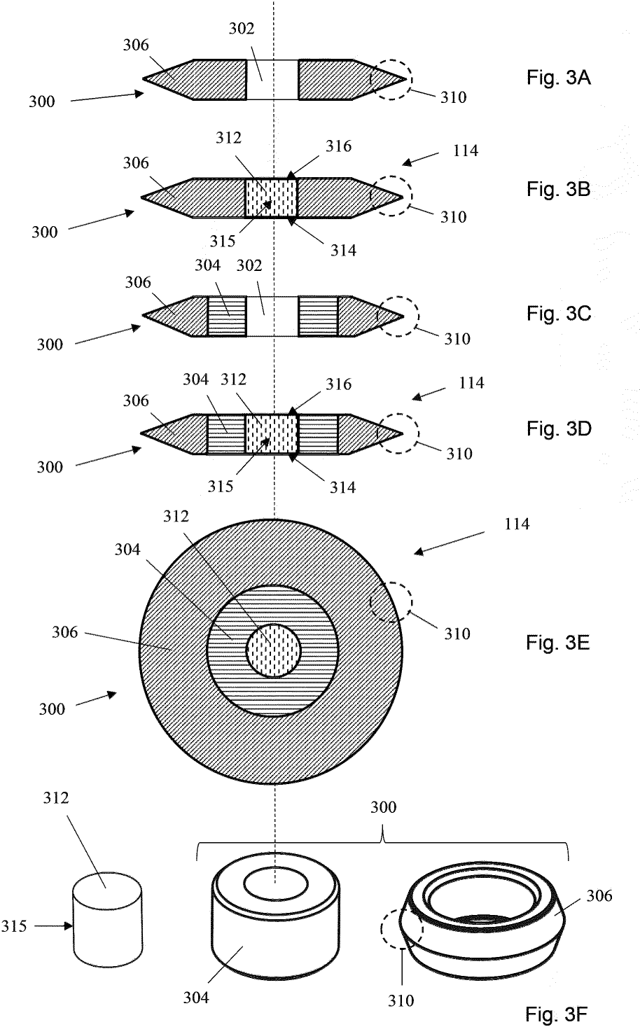

FIGS. 3A-3F show schematically embodiments of an electron source piece 114 and a carrier 300 for an electron emitter 312. FIGS. 3A-3D show cross sectional side views and FIG. 3E shows a cross sectional top view of embodiments. FIG. 3F shows exemplifying parts of an electron source piece 114 in a perspective view. An electron source piece 114 is formed by an electron emitter 312 being attached to a carrier 300.

FIG. 3A and FIG. 3C show schematically embodiments of a carrier 300 for an electron emitter 312, the carrier 300 comprising a center recess 302, adapted to receive an emitter 312 capable of emitting electrons via thermionic emission from an emitting surface 314 when heated on a back surface 316, a side surface 315, essentially perpendicular to the emitting surface 314, between the emitting surface 314 and the back surface 316, and a thermal break in a mechanical interface 310 adapted to mechanically mate with an emitter holder 120 adapted to hold the carrier 300. The back surface 316 may in embodiments be covered with a material preventing electron emission. FIG. 3B and FIG. 3D show embodiments of the carrier 300 with an electron emitter 312 mated in the recess 302 of the carrier 300.

The carrier 300 that is schematically shown in FIGS. 3A-3F is shaped so that it creates a first thermal break in a first mechanical interface 310 devised for mechanically mating with an emitter holder 120 adapted to hold the carrier 300, while at the same time covering the side surface 315 of the electron emitter 312, so that no electrons can leak from this side surface 315. In other words, the carrier 300 is preferably arranged so that it covers the side surface 315 of the electron emitter 312, at least the side surface 315 adjoining the emitting surface 314, so that no electrons can leak from this side surface 315. The electron emitter 312 is preferably arranged in the carrier 300 in such a way that the emitting surface 314 does not extend substantially beyond the carrier 300. If the emitting surface 314 is curved or domed to be more lens-shaped, there may be parts in the center of the emitting surface 314 that extend beyond the carrier 300, but the side surface 315 of the electron emitter 312 should preferably always be covered by the carrier 300.

### Mechanical Interface - Carrier Part

The carrier part of the mechanical interface 310, in FIGS. 3A-3F indicated with an intermittently drawn circle, has a geometrical shape adapted to have a minimal contact surface to the emitter holder 120 while providing sufficient mechanical support to keep the carrier in a stable position. The carrier part of the mechanical interface 310 is preferably adapted for form fitting with a corresponding mechanical interface of the emitter holder 120.

In embodiments, the carrier part of the mechanical interface 310 has a pointed or edged shape at one or more contact points adapted for mating with the emitter holder 120. Embodiments of the carrier 300 comprise a carrier part 306 in the shape of a ring having a tapered peripheral flange forming the mechanical interface 310 of the carrier, as shown in FIGS. 3A-3F.

### Intermediate and Outer Carrier Parts

The carrier 300, in embodiments as shown in FIGS. 3C-3F, comprises an intermediate carrier part 304 having the center recess 302, and an outer carrier part 306 adjoining the intermediate carrier part 304 and having the mechanical interface 310 of the carrier 300 on its peripheral rim. The electron emitter 312 is arranged in the intermediate carrier part 304 in such a way that the carrier part 304 covers the side surface 315 of the electron emitter 312 adjoining the emitting surface 314. In other words, the intermediate carrier part 304 is preferably arranged so that it covers the side surface 315 of the electron emitter 312, at least the side surface 315 adjoining the emitting surface 314, so that no electrons can leak from this side surface 315. The electron emitter 312 is preferably arranged in the intermediate carrier part 304 in such a way that the emitting surface 314 does not extend substantially beyond the intermediate carrier part 304. If the emitting surface 314 is curved or domed to be more lens-shaped, there may be parts in the center of the emitting surface 314 that extend beyond the carrier 300, but the side surface 315 of the electron emitter 312 should preferably always be covered by the carrier 300.

In such embodiments, the intermediate carrier part 304 preferably comprises a material facing the center recess 302 that has less hardness than the material of the electron emitter 312 intended to be received in the center recess 302. This enables an easy press fit or deformation fit between an electron emitter 312 and the intermediate carrier part 304 when the emitter 312 is mounted in the carrier 300. Similarly, the intermediate carrier part 304 preferably comprises a material facing its perimeter that has less hardness than the material of the outer carrier part 306. Embodiments of the intermediate carrier part 304 comprise tantalum or a derivative thereof, for example a tantalum rich alloy.

It is also an advantage that the outer carrier part 306 is in a harder material when it is positioned/pressed into the cathode holder 120. When this is the case, the outer carrier part 306 will be less deformed during assembly and the shape/geometry will remain, and hence the thermal break will remain intact.

In embodiments, the material of the emitter 312 is lanthanum hexaboride LaB₆, which is harder than tantalum. Other materials of the emitter are for example CE LaB₆ or tungsten.

The outer carrier part 306 preferably comprises a material at the mechanical interface 310 of the carrier that has more hardness than the intermediate carrier part 304. Again, this enables easy press fit or deformation fit now between the intermediate part 304 and the outer carrier part 306. The outer carrier part 306 preferably further comprises a material at the mechanical interface 310 of the carrier that has more hardness than the holder 120 intended to hold the carrier 300. This enables a smooth mating at the mechanical interface when attaching the electron source piece 114 to the holder 120, one of form fitting, press fitting or deformation fitting. Embodiments of the outer carrier part 306 comprise molybdenum or a derivative thereof, for example a molybdenum rich alloy. Molybdenum is harder than tantalum and also harder than lanthanum hexaboride of emitter embodiments. Other materials, for example steel, and other combinations of materials are also conceivable in further embodiments.

When the intermediate carrier part 304 is chosen in a material softer than the harder adjacent parts, i.e. outer carrier part 306 and electron emitter 312, it is possible to achieve an efficient mounting/assembling of electron source piece 114, due to that the softer intermediate carrier part 304 can be deformed when it is in position and by this deformation it will hold the outer carrier part 306 and the electron emitter 312 in position. As mentioned, this enables easy press fit or deformation fit between the carrier parts and the electron emitter 312. This also enables lower requirements on manufacturing tolerances and enables less complex design of the carrier part and the emitter.

Embodiments of an electron source piece 114 comprise an electron emitter 312 being form fitted, press fitted or deformation fitted with a softer adjoining intermediate carrier part 304, wherein the intermediate carrier part 304 is form fitted, press fitted or deformation fitted with a harder outer carrier part 306 and the outer carrier part 306 has said mechanical interface 310 of the carrier on its peripheral rim.

Embodiments of the carrier 300 comprise an intermediate carrier part 304 being ring shaped with its center recess 302 adapted for receiving and form fitting, press fitting or deformation fitting with a cylindrical electrons emitter, and an outer carrier part 306 being ring shaped with its center recess 302 adapted for receiving and form fitting, press fitting or deformation fitting with the intermediate carrier part 304 and having said mechanical interface 310 of the carrier on its peripheral rim, said parts being adapted such that the intermediate carrier part 304 and the outer carrier part 306 each has a surface flush with the emitting surface of the emitter 312 when fitted in the carrier 300. If the emitting surface 314 is curved or domed to be more lens-shaped, there may be parts in the center of the emitting surface that extend beyond the carrier 300, but the part of the emitting surface adjoining the intermediate carrier part 304 should preferably be flush with at least the intermediate carrier part 304.

Another embodiment of the carrier 300 for an electron emitter, comprises: a center recess 302 adapted to receive an emitter 312 capable of emitting electrons via thermionic emission from an emitting surface 314 when heated on a back surface 316; an intermediate carrier part 304 of a softer metal delimiting the center recess 302 and being adapted to attach the emitter 312 in the center recess 302; an outer carrier part 306 of a harder metal adjoining the intermediate carrier part 304 and having a thermal break in a mechanical interface 310 of the outer carrier part adapted to mechanically mate with a holder 120.

The carrier 300 preferably always comprises a carrier part 304, 306 that covers the side surface 315 of the electron emitter 312, at least the side surface 315 adjoining the emitting surface 314, so that no electrons can leak from this side surface 315. The electron emitter 312 is preferably arranged in the carrier 300 in such a way that the emitting surface 314 does not extend substantially beyond the carrier 300, at least the part of the carrier 300 adjoining the emitting surface 314. If the emitting surface 314 is curved or domed to be more lens-shaped, there may be parts in the center of the emitting surface 314 that extend beyond the carrier 300, but the side surface 315 of the electron emitter 312 should preferably always be covered by the carrier 300. The back surface 316 may in embodiments be covered with a material preventing electron emission. If the carrier 300 also comprises a separate outer carrier part 306, this outer carrier part 306 may have any shape that creates a thermal break in the first mechanical interface 310 between the carrier 300 and the emitter holder 120, while at the same time ensuring that the electron source piece 114 has a well defined position within the emitter holder 120.

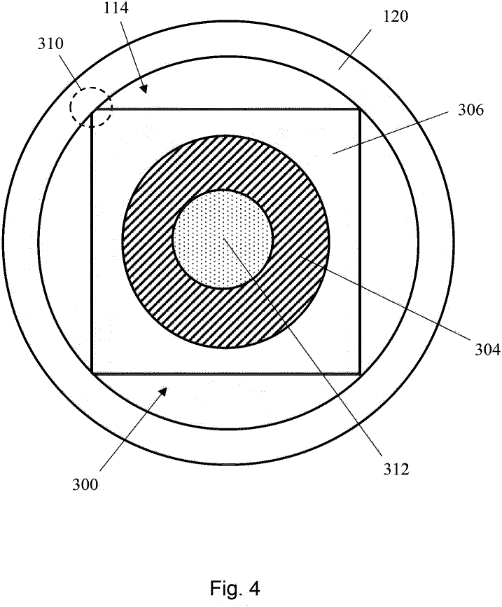

FIG. 4 schematically shows another embodiment of an electron source piece 114 comprising a carrier 300 and an electron emitter 312. In the embodiment schematically illustrated in FIG. 4, the thermal break in the first mechanical interface 310 is created by the outer carrier part 306 being shaped so that the carrier 300 only mechanically mates with the emitter holder 120 at certain points. The electron emitter 312 is preferably arranged in the intermediate carrier part 304 in such a way that the emitting surface 314 does not extend substantially beyond the intermediate carrier part 304. If the emitting surface 314 is curved or domed to be more lens-shaped, there may be parts in the center of the emitting surface 314 that extend beyond the intermediate carrier part 304, but the side surface 315 of the electron emitter 312 should preferably always be covered by the intermediate carrier part 304. The materials of the different parts may e.g. be as indicated above for the embodiments of FIGS. 3A-3F.

As explained above, the carrier 300 preferably always comprises a carrier part that covers the side surface 315 of the electron emitter 312, at least the side surface 315 adjoining the emitting surface 314, so that no electrons can leak from this side surface 315. However, it is not necessary that the carrier 300 comprises any further parts, if the thermal break in the first mechanical interface 310 can be created in another way.

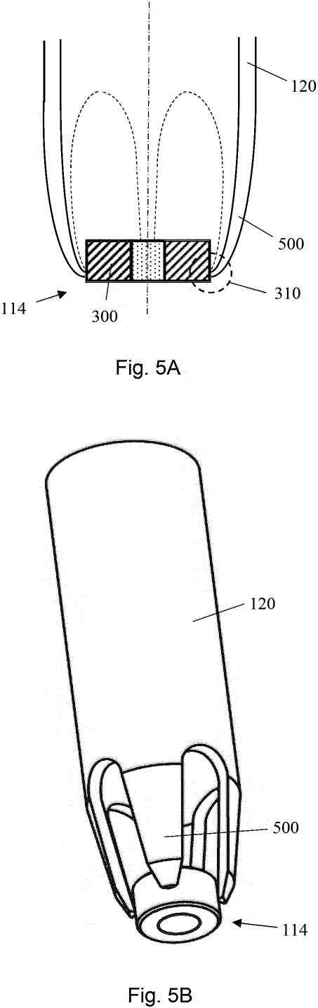

FIGS. 5A-B schematically shows an embodiment of a cathode holder 120 that is shaped to create the first thermal break. In this embodiment, the cathode holder 120 is arranged with “claws” 500 extending from the end, and the first mechanical interface 310 is created by the end of these claws 500 mating with the carrier 300.

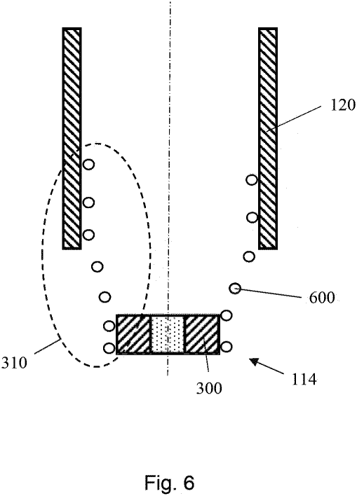

FIG. 6 schematically shows an embodiment of a carrier arrangement that creates the thermal break in a different way. In this embodiment, the first mechanical interface 310 is created by a coil 600, e.g. made of tungsten, that is arranged between the cathode holder 120 and the electron source piece 114, and mates with the carrier 300.

The carrier 300 may in the embodiments of FIGS. 5A-B and FIG. 6 comprise only one cylindrical carrier part with a recess for the emitter 312, since this is enough to ensure that the side surface 315 of the electron emitter 312, at least the side surface 315 adjoining the emitting surface 314, is covered, so that no electrons can leak from this side surface 315. The electron emitter 312 is preferably arranged in the carrier 300 in such a way that the emitting surface 314 does not extend substantially beyond the carrier 300. If the emitting surface 314 is curved or domed to be more lens-shaped, there may be parts in the center of the emitting surface 314 that extend beyond the carrier 300, but the side surface 315 of the electron emitter 312 should preferably always be covered by the carrier 300. The materials of the different parts may e.g. be as indicated above for the embodiments of FIGS. 3A-3F.

Embodiments have been disclosed herein by way of examples, further variants are conceivable within the scope of the described embodiments. The illustrated electron emitters are all cylindrical, but the electron emitter may have any shape that makes technical sense. This also means that the back surface of the emitter is not necessarily parallel with the emitting surface.

### LIST OF ITEMS AND REFERENCE NUMERALS

List of items and refrence numerals

| | |
|---|---|
| 100 | Metal 3D printer |
| 102 | Electron beam |
| 106 | Cathode arrangement |
| 108 | Powder bed |
| 110 | Anode arrangement |
| 111 | Electron channel of anode |
| 112 | Cathoder holder system of cathode holder system members |
| 114 | Electron source piece |
| 119 | Emitter holder envelope surface |
| 120 | Emitter Holder |
| 121 | Emitter holder channel |
| 122 | Second thermal break |
| 124 | Second mechanical interface |
| 125 | Intermediate holder channel |
| 128 | Third mechanical interface |
| 130 | Outer holder |
| 132 | Fourth mechanical interface |
| 134 | Cathode assembly holder |
| 135 | Assembly holder flange of cathode assembly holder |
| 136 | Bore for a lock screw on flange of cathode assembly holder |
| 138 | Bore for a lock screw in intermediate holder |
| 140 | Lock screw of second mechanical interface of intermediate holder |
| 142 | Annulus of outer holder |
| 144 | Tapered peripheral surface of intermediate holder |
| 145 | Perimeter flange |
| 146 | Straight annular surface of outer holder |
| 148 | Straight peripheral surface of intermediate holder |
| 150 | Energy beam generator |
| 152 | Energy beam |
| 153 | Chassis of vacuum chamber |
| 154 | Vacuum chamber |
| 156 | Abutting surface of perimeter flange |
| 158 | Tapered perimeter surface of perimeter flange |
| 300 | Carrier for an electron emitter, emitter carrier |
| 302 | Center recess of carrier |
| 304 | Intermediate part of carrier – perferably soft metal |
| 306 | Outer part of carrier – preferably hard metal |
| 310 | First mechanical interface, mechanical interface of outer part of carrier |
| 312 | Electron emitter |
| 314 | Emitting surface of emitter |
| 315 | Side surface of emitter |
| 316 | Back surface of emitter |

1. A metal 3D printer having an electron gun adapted to direct an electron beam of a cathode arrangement onto a metal material via an anode arrangement, wherein the electron beam is generated by a back heated electron emitter, capable of emitting electrons via thermionic emission from an emitting surface when heated on a back surface, and comprising a side surface, essentially perpendicular to the emitting surface, between the emitting surface and the back surface, the metal 3D printer comprising:
an electron source piece, comprising the electron emitter attached to a carrier in such a way that the carrier covers the side surface of the electron emitter adjoining the emitting surface;
a cathode holder system comprising one or more cathode holder system members adapted to hold the electron source piece in a position in relation to an anode arrangement; and
a first thermal break in a first mechanical interface adapted to mate an emitter holder of the cathode holder system with the electron source piece.

2. The metal 3D printer of claim 1, wherein the electron emitter is attached to the carrier in such a way that the emitting surface of the electron emitter does not extend substantially beyond the part of the carrier adjoining the emitting surface.

3. The metal 3D printer of claim 1, further comprising at least one further thermal break between two of the cathode holder system members.

4. The metal 3D printer of claim 1, further comprising a second thermal break in a second mechanical interface adapted to mate the emitter holder with an intermediate holder of the cathode holder system.

5-8. (canceled)

9. The metal 3D printer of claim 1, further comprising a laser adapted to generate an energy beam for heating the back of the electron emitter, the laser for example being a CO2 laser.

10. The metal 3D printer of claim 1, wherein the back surface of the electron emitter is covered with a material preventing electron emission.

11. A cathode holder system for an electron gun adapted to direct an electron beam of a cathode arrangement via an anode arrangement, wherein the electron beam is generated by a back heated electron emitter, capable of emitting electrons via thermionic emission from an emitting surface when heated on a back surface, and comprising a side surface, essentially perpendicular to the emitting surface, between the emitting surface and the back surface, comprising:
a set of one or more cathode holder system members adapted to hold an electron source piece, comprising the electron emitter attached to a carrier in such a way that the carrier covers the side surface of the electron emitter adjoining the emitting surface, in a position in relation to an anode arrangement; and
a first thermal break in a first mechanical interface adapted to mate an emitter holder of the cathode holder system with the electron source piece.

12. The cathode holder system of claim 11, wherein the electron emitter is attached to the carrier in such a way that the emitting surface of the electron emitter does not extend substantially beyond the part of the carrier adjoining the emitting surface.

13. The cathode holder system of claim 11, further comprising at least one further thermal break between two of the cathode holder system members.

14. The cathode holder system of claim 11, further comprising a second thermal break in a second mechanical interface adapted to mate the emitter holder with an intermediate holder of the cathode holder system.

15-17. (canceled)

18. The cathode holder system of claim 11, wherein the back surface of the electron emitter is covered with a material preventing electron emission.

19. An electron source piece comprising an electron emitter attached to a carrier, the electron emitter being capable of emitting electrons via thermionic emission from an emitting surface when heated on a back surface, and comprising a side surface, essentially perpendicular to the emitting surface, between the emitting surface and the back surface, and the carrier having a thermal break in a mechanical interface adapted for mechanically mating with an emitter holder, wherein the electron emitter is attached to the carrier in such a way that the carrier covers the side surface of the electron emitter adjoining the emitting surface.

20. The electron source piece of claim 19, wherein the electron emitter is attached to the carrier in such a way that the emitting surface of the electron emitter does not extend substantially beyond the part of the carrier adjoining the emitting surface.

21. The electron source piece of claim 19, wherein the mechanical interface of the carrier has a shape that minimizes the surface area of contact between the carrier and the emitter holder at one or more mating points.

22. The electron source piece of claim 19, comprising:
an electron emitter being form fitted, press fitted or deformation fitted with a softer adjoining intermediate carrier part;
the intermediate carrier part being form fitted, press fitted or deformation fitted with a harder outer carrier part; and
the outer carrier part having said mechanical interface of the carrier on its peripheral rim.

23. The electron source piece of claim 19, wherein the material of the emitter is lanthanum hexaboride.

24. The electron source piece of claim 19, wherein the intermediate carrier part comprises tantalum or a derivative thereof.

25. The electron source piece of claim 19, wherein the outer carrier part comprises molybdenum or a derivative thereof.

26. The electron source piece of claim 19, comprising:
a cylindrical electrons emitter;
an intermediate carrier part being ring shaped with its center recess form fitted with the cylindrical electrons emitter; and
an outer carrier part being ring shaped with its center recess form fitted, press fitted or deformation fitted with the intermediate carrier part and having the mechanical interface of the carrier on its peripheral rim;
wherein the intermediate carrier part and the outer carrier part each has a surface flush with the emitting surface of the emitter when fitted together.

27. The electron source piece of claim 19, wherein the back surface of the electron emitter is covered with a material preventing electron emission.

28-43. (canceled)
